(19) United States
(12) Patent Application Publication
(10) Pub. No.: US 2011/0179330 A1
(43) Pub. Date: Jul. 21, 2011

(54) WIRELESS COMMUNICATION TERMINAL AND COMMUNICATION CONTROL METHOD

(75) Inventor: Naohisa Matsumoto, Yokohama-shi (JP)

(73) Assignee: KYOCERA CORPORATION, Kyoto-shi, Kyoto (JP)

(21) Appl. No.: 13/056,587

(22) PCT Filed: Jul. 28, 2009
(86) PCT No.: PCT/JP2009/063417

§ 371 Date: Jan. 28, 2011

(30) Foreign Application Priority Data
Jul. 30, 2008 (JP) 2008-196697
Jul. 30, 2008 (JP) 2008-196727

(51) Int. Cl. H03M 13/05; H04L 1/08; G06F 11/10; G06F 11/14

(52) U.S. Cl. 714/748; 714/752; 714/E11.032; 714/E11.131

(57) ABSTRACT

A wireless communication terminal having a plurality of antennas with a variable relative distance includes a decoder for iterative decoding of reception signals including an error-correcting code received by the plurality of antennas) and a control unit for controlling an iteration count of decoding by the decoder in accordance with a distance between the antennas detected by an antenna distance detection unit for detecting the distance between the plurality of antennas.

### CROSS REFERENCE TO RELATED APPLICATIONS

This application claims priority to and the benefit of Japanese Patent Application No. 2008-196697 (filed on Jul. 30, 2008) and Japanese Patent Application No. 2008-196727 (filed on Jul. 30, 2008), the entire contents of which are incorporated herein by reference.

### TECHNICAL FIELD

The present invention relates to wireless communication terminals and communication control methods.

### BACKGROUND ART

In wireless communications such as mobile communications, data (signal) errors are typically caused in communication paths as affected by fading or multipath. As techniques to correct such errors, Turbo codes and LDPC (Low Density Parity Check) have been employed in recent years. Turbo codes can be obtained by inputting data transmitted to a plurality of decoders in different orders of bits by a transmission side. A reception side (terminal side) has a plurality of decoders to decode reception data and performs iterative decoding by feeding output of the decoders as input back to the decoders. Such iterative decoding may improve accuracy in error correction to the reception data.

As described above, error correction using the Turbo codes and LDPC requires iterative decoding, and decoding characteristics of data are enhanced more as the number of iterative decoding is increased. However, there is a limit of the decoding characteristics attainable. That is, with over a certain iteration count, the decoding characteristics cannot be improved any better. Accordingly, it is a conventional manner to obtain, in advance, an iteration count of decoding at which the decoding characteristics converge amply (hereinafter, referred to as a “convergence count”) and to carry out iterative decoding as many times as the convergence count.

However, there is a problem that a time necessary for decoding is extended with increase of the iteration count of decoding, which increases power consumption. As a method to address this problem, there is suggested a technique, as a conventional art, to vary the iteration count of decoding in accordance with reception quality (state of a communication channel) measured from pilot signals received (see Patent Document 1 and Patent Document 2). FIG. 11 shows a schematic block diagram of a wireless communication terminal which controls the iteration count of decoding according to the conventional art. In FIG. 11, a channel quality calculation unit 230 calculates (estimates) the reception quality using the pilot signals received by a reception unit 210 via an antenna ANT 3 and transmits a result of calculation to an iteration count calculation unit 240. The iteration count calculation unit 240 controls the iteration count of decoding by an iterative decoder 220 in accordance with the reception quality (channel quality). That is, if it is estimated that the channel quality is good and that there are only few errors in the signals received, the iteration count of decoding is set less than the convergence count based on a recognition that good decoding characteristics can be obtained with a less iteration count of decoding. However, the conventional art to control the iteration count of decoding by calculating the channel quality has a problem that calculation of the channel quality places a load and increases power consumption, that is, battery consumption. Therefore, if a remaining battery level (remaining power, battery level available to supply to the terminal itself) is low, it is not ideal to control the iteration count of decoding according to the conventional art.

Incidentally, predominating wireless communication terminals in recent years have a plurality of antennas to communicate with a diversity scheme. Space diversity, for example, utilizes a phenomenon that, when signals are received by a plurality of antennas located separately from one another, a correlation of the reception signals is generally diminished and the reception signals vary individually. Accordingly, those wireless communication terminals improve reliability of the reception signals, by combining the plurality of signals received by the plurality of antennas in predetermined processing or by selecting reception signals having a best reception level.

In the wireless communication terminals having a plurality of antennas as stated above, relative positions of the plurality of antennas may vary. For instance, taking cellular phone terminals as examples, flip phones having two housings movably joined each other with hinges and slide phones having two housings one of which slides along the other may have antennas in respective housings. A distance between these antennas varies as the housings are moved, and thus a diversity effect differs in accordance with a positional relationship of the housings. That is, when the distance between the antennas is long and the correlation of the antennas is low, the quality of the reception signals is better in comparison with that in a case when the distance between the antennas is short and signals are received by a single antenna substantially. However, there has not yet been suggested a technique, when employing error correction by the above iterative decoding for the wireless communication terminal having a plurality of antennas, to control the iteration count of decoding in accordance with the reception quality varying according to a relative distance between the plurality of antennas.

### RELATED ART DOCUMENTS

### Patent Documents

Patent Document 1: Japanese Patent Laid-Open No. 2001-230679
Patent Document 2: Japanese Patent Laid-Open No. 2002-152056

### SUMMARY OF SOME EXAMPLE EMBODIMENTS

In one example embodiment, a wireless communication terminal (capable of implementing diversity reception,) having a plurality of antennas with a variable relative distance includes: (a reception unit for combining or selecting a plurality of reception signals received by the plurality of antennas;) a decoder (Turbo decoder) for iterative decoding of the reception signals including an error-correcting code received by the plurality of antennas; an antenna distance detection unit for detecting a distance between the plurality of antennas; (a memory unit for storing a table of iteration counts of decoding by the decoder corresponding to the distances between the antennas;) and a control unit for controlling an iteration count of decoding by the decoder in accordance with the distance between the antennas detected.

According to another embodiment of the present invention, in the wireless communication terminal (capable of implementing diversity reception,) having the plurality of antennas with the variable relative distance, the control unit, if the distance between the antennas is over a predetermined value, reduces the iteration count of decoding in comparison with the iteration count of decoding when the distance between the antennas is under the predetermined value.

According to another embodiment of the present invention, the wireless communication terminal (capable of implementing diversity reception,) having the plurality of antennas with the variable relative distance further includes a channel quality calculation unit for calculating quality of a communication channel from the reception signals received by the plurality of antennas, wherein the control unit, if the distance between the antennas is under the predetermined value, controls the iteration count of decoding in accordance with the quality of the communication channel calculated by the channel quality calculation unit.

According to yet another embodiment of the present invention, the wireless communication terminal (capable of implementing diversity reception,) having the plurality of antennas with the variable relative distance further includes (a buffer for buffering the reception signals including the error-correcting code received by the plurality of antennas,) a determination unit (detection unit) for determining whether data decoded by the decoder has an error, and a retransmission request unit for requesting retransmission of data based on a result of determination by the determination unit, wherein the control unit further controls the iteration count of decoding by the decoder in accordance with the number of retransmission requests requested by the retransmission request unit.

According to yet another embodiment of the present invention, the wireless communication terminal (capable of implementing diversity reception,) having the plurality of antennas with the variable relative distance further includes a detection unit for detecting a remaining power level available to supply to the wireless communication terminal, wherein the control unit, if the remaining power level detected by the detection unit is under a predetermined value, controls the iteration count of decoding by the decoder in accordance with the distance between the antennas detected by the antenna distance detection unit.

According to yet another embodiment of the present invention, the wireless communication terminal (capable of implementing diversity reception,) having the plurality of antennas with the variable relative distance further includes a channel quality calculation unit for calculating quality of a communication channel from the reception signals received by the plurality of antennas, wherein the control unit, based on the remaining power level detected by the detection unit, switches between control of the iteration count of decoding in accordance with the quality of the communication channel calculated by the channel quality calculation unit and control of the iteration count of decoding in accordance with the distance between the antennas detected by the antenna distance detection unit.

According to one embodiment of the present invention, a wireless communication terminal having a decoder for iterative decoding of a reception signal including an error-correcting code includes: a detection unit for detecting a remaining power level available to supply to the wireless communication terminal; and a control unit for controlling the iteration count of decoding by the decoder in accordance with the remaining power level detected.

Although solving means of the present invention are described as apparatus as above, it should be understood that the present invention can also be implemented as method, program, recording medium recording the program, hence they are included within the scope of the present invention. Each step of a method and program uses an arithmetic processing unit such as a CPU, a DSP and the like in processing data, as appropriate, while storing input data and processed or generated data in a recording apparatus device such as an HDD, a memory and the like.

For example, as a method implementing the present invention, a communication control method of a wireless communication terminal (capable of implementing diversity reception,) having a plurality of antennas with a variable relative distance includes the steps of: (combining or selecting a plurality of reception signals received by the plurality of antennas;) iteratively decoding reception signals including an error-correcting code received by the plurality of antennas; detecting a distance between the plurality of antennas; and controlling an iteration count of decoding by the decoder in accordance with the distance between the antennas detected at the step of detection.

Additionally, as a method implementing the present invention, a communication control method of a wireless communication terminal having a decoder for iterative decoding of a reception signal including an error-correction signal includes the steps of: detecting a remaining power level available to supply to the wireless communication terminal; and controlling an iteration count of decoding by the decoder in accordance with the remaining power level detected at the step of detection.

### BRIEF DESCRIPTION OF DRAWINGS

FIG. 1 is a schematic diagram of a wireless communication terminal according to one embodiment of the present invention;

FIG. 2 is a schematic block diagram of a wireless communication terminal according to a first embodiment of the present invention;

FIG. 3 is a flowchart illustrating an exemplary processing by a wireless communication terminal 100 according to the first embodiment of the present invention;

FIG. 4 is a schematic block diagram of a wireless communication terminal according to a second embodiment of the present invention;

FIG. 5 shows flowcharts illustrating an exemplary processing by a wireless communication terminal 100A according to the second embodiment of the present invention;

FIG. 6 is a schematic block diagram of a wireless communication terminal according to a third embodiment of the present invention;

FIG. 7 shows flowcharts illustrating an exemplary processing by a wireless communication terminal 100B according to the third embodiment of the present invention;

FIG. 8 is a diagram illustrating a relationship between a mode of a remaining battery level and a maximum iteration count of decoding set for an iterative decoder 120;

FIG. 9 is a schematic block diagram of a wireless communication terminal according to a fourth embodiment of the present invention;

FIG. 10 is a flowchart illustrating an exemplary processing by a wireless communication terminal 100C according to the fourth embodiment of the present invention; and

FIG. 11 is a schematic block diagram of a wireless communication terminal for controlling the iteration count of decoding according to a conventional art.

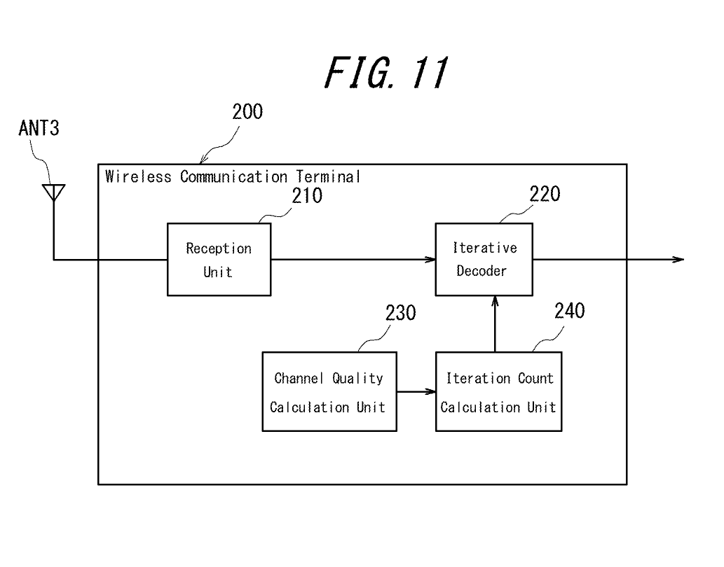

### DESCRIPTION OF EMBODIMENTS

A wireless communication terminal according to one embodiment of the present invention will be described in detail with reference to the accompanying drawings. The wireless communication terminal may be any mobile or portable electronics device such as a mobile phone terminal, a notebook computer, a PDA (Personal Digital Assistance), a portable game machine, a portable audio player, a portable video player, a portable electronic dictionary, a portable electronic book reader, and the like.

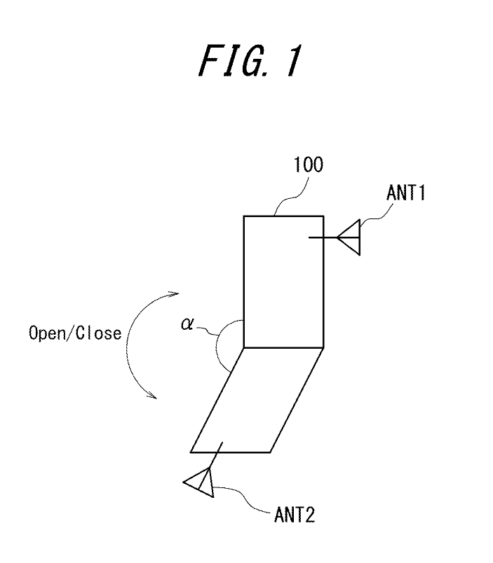

FIG. 1 is a schematic diagram of a wireless communication terminal according to one embodiment of the present invention. As shown in FIG. 1, for example, a wireless communication terminal 100 is a flip-type mobile phone having two housings and two antennas ANT 1 and ANT 2 positioned in the housings, respectively. The wireless communication terminal can open/close these housings. In an open state, the housings are separated from each other as shown in FIG. 1 and, in a close state (not shown), the housings are closely located to each other. In an example shown in FIG. 1, when the wireless communication terminal 100 is in the open state, the ANT 1 and ANT 2 are separated from each other with a sufficiently long relative distance and less correlated, allowing the terminal to obtain an adequate diversity effect. In contrast, when the wireless communication terminal 100 is in the close state, the ANT 1 and the ANT 2 have a short relative distance and thus operate as a single antenna, substantially. It is to be understood that the present invention is not limited to the flip-type mobile phone but is also applicable to any wireless communication terminal having a plurality of antennas with a variable relative distance. Additionally, although the wireless communication terminal has two antennas in the present embodiment, the present invention is not limited thereto but is also applicable to a wireless communication terminal having three or more antennas.

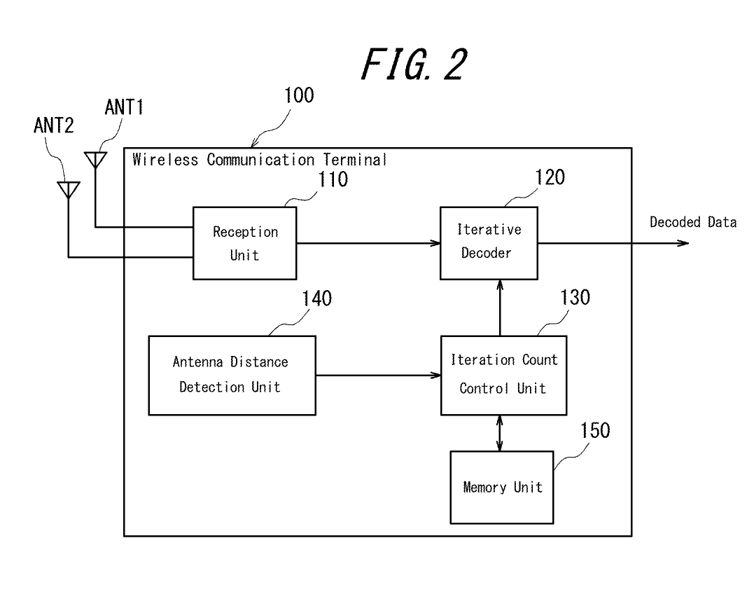

A first embodiment of the present invention is described first. FIG. 2 is a schematic block diagram of a wireless communication terminal according to the first embodiment of the present invention. The wireless communication terminal 100 includes a reception unit 110, an iterative decoder 120, an iteration count control unit 130, an antenna distance detection unit 140, a memory unit 150 and two antennas ANT 1, ANT 2. The reception unit 110 carries out a predetermined processing to signals received from the antennas ANT 1, ANT 2. For example, the reception unit 110 includes a demodulation unit, a switch (not shown) and the like and selects signals with a strong reception level, among signals received from the antennas ANT 1, ANT 2. Alternatively, if the wireless communication terminal 100 has three or more antennas, the reception unit 110 combines reception signals using a maximal-ratio combining scheme and the like, for example, in order to obtain the best reception signal. The signals received by the antennas ANT 1, ANT 2 include Turbo codes (error-correcting codes) for error correction. Then, the reception unit 110 transmits processed data to the iterative decoder 120. The iterative decoder 120 decodes using the error-correcting codes included in the data transmitted from the reception unit 110. Like general Turbo decoders, for example, the iterative decoder 120 has two decoders, an interleaver and a de-interleaver, and carries out iterative decoding based on an error correction scheme. Since iterative decoding using the Turbo codes is a well-known scheme, a detailed description thereof is omitted here.

The antenna distance detection unit 140 detects a distance between the ANT 1 and the ANT 2. In the flip-type mobile phone, for example, the antenna distance detection unit 140 detects the distance between the antennas based on a degree of the housings open (a degree a in FIG. 1). Alternatively, in a slide-type mobile phone having antennas in two housings, respectively, the antenna distance detection unit 140 detects the distance between the antennas based on a slide state. The iteration count control unit 130 determines an iteration count of decoding by the iterative decoder 120 based on the distance between the antennas detected by the antenna distance detection unit 140. The iteration count is set in accordance with the distance between the antennas. The memory unit 150 stores a table of iteration counts corresponding to the distances between the antennas.

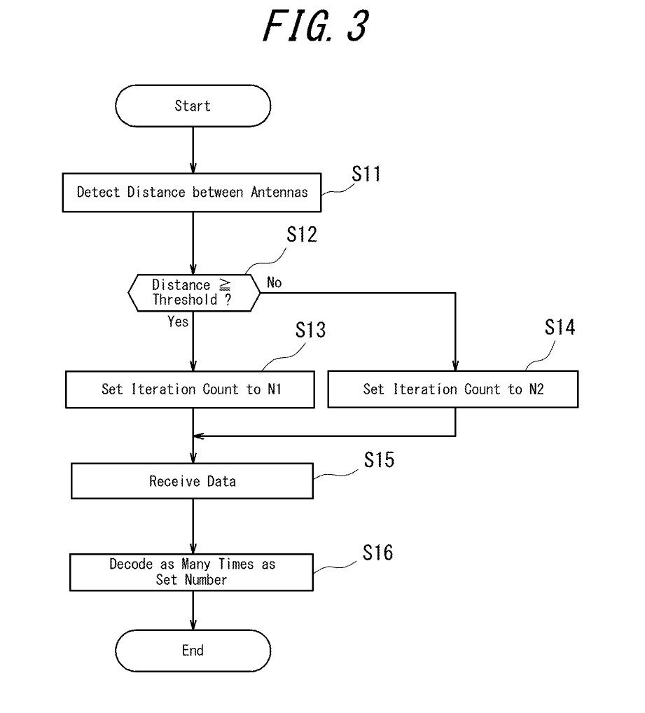

Next, processing by the wireless communication terminal 100 according to the present invention is described with reference to a flowchart. FIG. 3 is a flowchart of exemplary processing by the wireless communication terminal 100 according to the first embodiment of the present invention. First, at step S11, the antenna distance detection unit 140 detects the distance between the ANT 1 and the ANT 2 and transmits the distance between the antennas to the iteration count control unit 130. The iteration count control unit 130 sets (controls) the iteration count of decoding based on the table of a relationship between the iteration count and the distance between the antennas stored in the memory unit 150. The following is the table stored in the memory unit 150, by way of example.

TABLE 1

| Distance between Antennas | Iteration Count |
|---|---|
| A ≦ Distance | N1 |
| Distance < A | N2 |

A: Threshold of distance between the antennas, N2 ≧ N1

Based on the table shown in Table 1, the iteration count control unit 130 sets the iteration count “N2” if the distance between the antennas is under a threshold A, while setting the iteration count “N1” if the distance between the antennas is equal to or over the threshold A (steps S12 to S14). Here, the threshold A is a value at which, if the distance between the antennas is equal to or over the threshold A, the ANT 1 and the ANT 2 are less correlated and can receive signals, substantially as two antennas. The iteration counts satisfy N2>N1, which is based on recognition that the quality of the reception signal is good when a correlation between the ANT 1 and the ANT 2 is low. That is, it is based on that, in this state, the iteration count of decoding can be set less than that for when the distance between the antennas is short and the antennas receive signals substantially as a single antenna. Additionally, since the reception quality is good if the distance between the antennas is over the threshold A, the iteration count N1 can be set less than a convergence count (iteration count N2) described above. After the iteration count is set at step S13 or step S14, the reception unit 100 receives data (step S15), and the iterative decoder 120 decodes the data received, in accordance with the iteration count (step S16).

The above first embodiment, different from a conventional art which uselessly iterates decoding in accordance with a predetermined convergence count even when the reception quality is good and decoding characteristics converge quickly, takes advantage of a diversity scheme and reduces the iteration count of decoding when the correlation between the antennas is low and the reception quality is good, and thus can reduce a time and power consumption necessary for decoding in comparison with the conventional art.

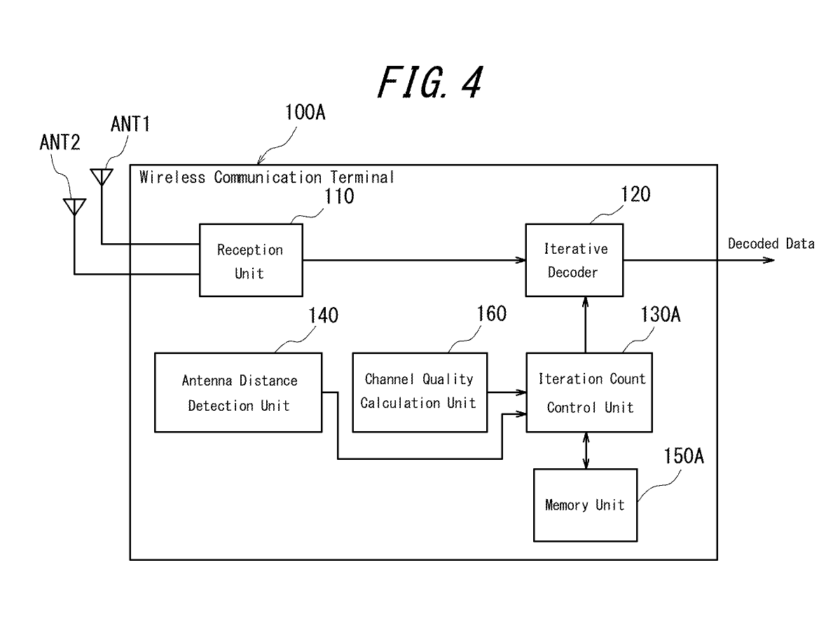

Next, a second embodiment of the present invention is described. FIG. 4 is a schematic block diagram of a wireless communication terminal according to the second embodiment of the present invention. In FIG. 4, the same functional units as those of the wireless communication terminal 100 in FIG. 2 are denoted by identical reference signs and descriptions thereof are omitted. A wireless communication terminal 100A further includes a channel quality calculation unit 160. The channel quality calculation unit 160 calculates the reception quality (channel quality) using the reception signals received by the antennas ANT 1 and ANT 2. The reception quality is obtained by calculating SIR (Signal to Interference Ratio) using, for example, pilot signals included in the reception signals. Otherwise, RSSI (Received Signal Strength Indicator), CIR (Carrier To Interference Ratio), CINR (Carrier to Interference plus Noise Ratio), SINR (Signal to Interference plus Nose Ratio) and the like can be used. An iteration count control unit 130A sets the iteration count of decoding based on the distance between the antennas detected by the antenna distance detection unit 140 and the channel quality calculated by the channel quality calculation unit 160. A memory unit 150A stores a table of the iteration counts corresponding to the distances between the antennas and the channel qualities.

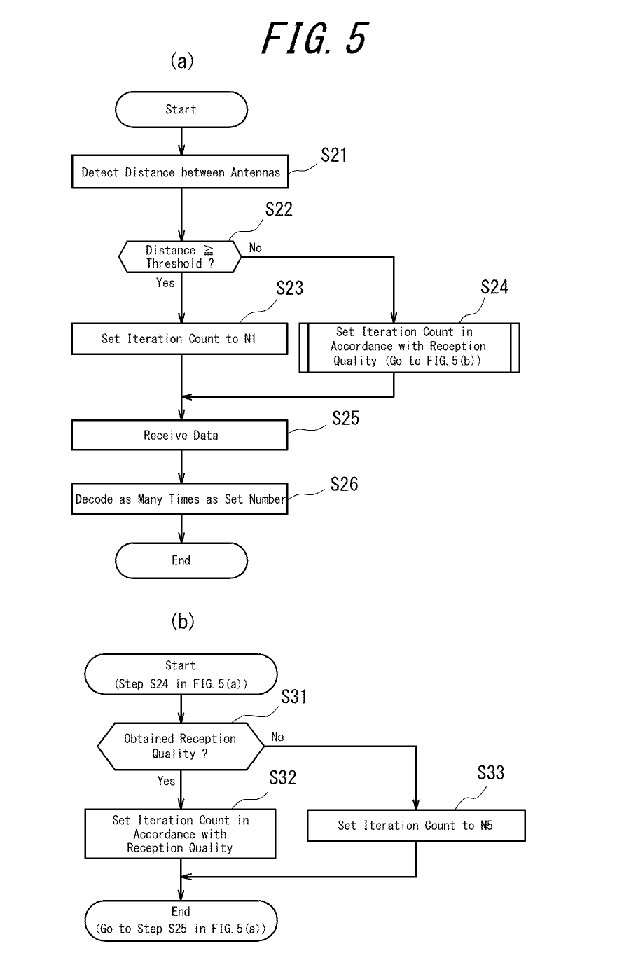

Next, processing by the wireless communication terminal according to the second embodiment of the present invention is described with reference to flowcharts. FIG. 5(a), (b) are flowcharts of exemplary processing by the wireless communication terminal 100A according to the second embodiment of the present invention. First, at step S21, the antenna distance detection unit 140 detects the distance between the two antennas ANT 1 and ANT 2 and transmits the distance to the iteration count control unit 130A. The iteration count control unit 130A sets the iteration count of decoding based on the table of the relationship between the iteration count and the distance between the antennas stored in the memory unit 150. The following is the table stored in the memory unit 150, by way of example.

TABLE 2

| Distance between Antennas | Iteration Count |
|---|---|
| A ≦ Distance | N1 |

| | | |
|---|---|---|
| Distance < A | C ≦ Reception Quality | N2 |
| | D ≦ Reception Quality < C | N3 |
| | Reception Quality < D | N4 |

A: Threshold of distance between the antennas
C, D: Thresholds of reception quality (C > D), N4 ≧ N3 ≧ N2 ≧ N1

If the distance between the antennas is equal to or over the threshold A, the iteration count control unit 130A sets the iteration count to “N1” based on the table shown in Table 2 (step S23). In contrast, if the distance between the antennas is under the threshold A, the iteration count control unit 130A proceeds to step S24 to set the iteration count in accordance with the reception quality. FIG. 5(b) is an exemplary flowchart of processing to set the iteration count in accordance with the reception quality. First, at step S31, the channel quality calculation unit 160 determines whether the reception quality is already obtained, that is, whether data (pilot signals and the like) that enable to calculate the reception quality (channel quality) are already obtained. If the channel quality calculation unit 160 determines that the reception quality is not obtained, the processing proceeds to step S33 where the iteration count control unit 130A sets the iteration count “N5”. The “N5” is the convergence count stated above and, if the distance between the antennas is short and the antennas receive the signals substantially as a single antenna and thus the reception quality is not good, is set to a count at which the decoding characteristics sufficiently converge. If it is determined at step S31 that the reception quality is already obtained, the processing proceeds to step S32 where the iteration count control unit 130A sets the iteration count in accordance with the reception quality based on the above Table 2. That is, if the reception quality is equal to or over the threshold C, the iteration count control unit 130A sets the iteration count to “N2”. If the reception quality is equal to or over the threshold D and under the threshold C, the iteration count control unit 130A sets the iteration count to “N3”. In addition, if the reception quality is under the threshold D, the iteration count control unit 130A sets the iteration count “N4”. Here, the thresholds of the reception quality satisfy C>D, whereas the iteration counts satisfy N4>N3>N2>N1. This, similarly to the first embodiment, is based on the recognition that the reception quality is good if the correlation between the ANT 1 and the ANT 2 is low. Moreover, if the reception quality is good when the distance between the antennas is short and the antennas receive the signals substantially as a single antenna, the iteration count is set less than that for when the reception quality is not good. Since the reception quality is good if the distance between the antennas is over the threshold A, the iteration count N1 can be set less than the conversion count. After setting of the iteration count at step S32 or step S33, the processing returns to step S25 in FIG. 5(a) where the reception unit 110 receives data. Then, the iterative decoder 120 decodes the data received, in accordance with the iteration count (step S26).

The second embodiment, in addition to the advantage according to the first embodiment, has advantages to be able to reduce the iteration count of decoding in accordance with the reception quality even if the distance between the antennas is short and the antennas receive the signals substantially as a single antenna, and also to reduce the time and power consumption necessary for decoding.

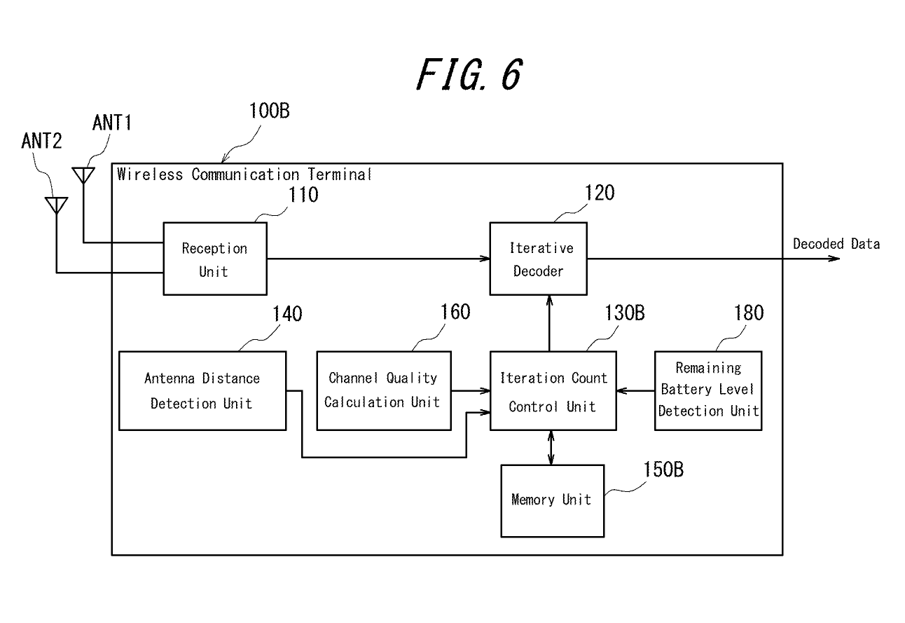

Next, a third embodiment of the present invention is described. FIG. 6 is a schematic block diagram of a wireless communication terminal according to the third embodiment of the present invention. In FIG. 6, the same functional units as those of the wireless communication terminal 100 shown in FIG. 2 are denoted by identical reference signs and descriptions thereof are omitted. A wireless communication terminal 100B further includes a remaining battery level detection unit 180. The remaining battery level detection unit 180 detects a remaining battery level (remaining power, battery levels available to supply to the terminal itself). The memory unit 150B stores a table of the iteration counts of decoding corresponding to the distances between the antennas, the remaining battery levels and the channel qualities.

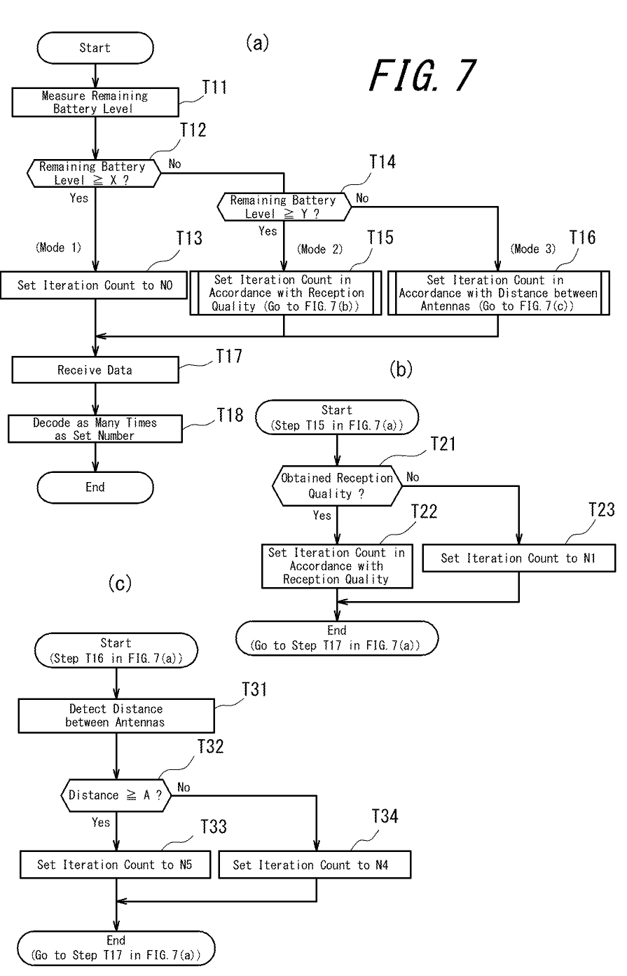

Next, processing by the wireless communication terminal 100B according to the present invention is described with reference to flowcharts. FIG. 7 shows flowcharts of exemplary processing by the wireless communication terminal 100B according to the third embodiment of the present invention. First, at step T11, the remaining battery level detection unit 180 measures (detects) the remaining battery level. At step T12, the iteration count control unit 130B determines whether the remaining battery level is equal to or over a predetermined threshold X. If determining that the remaining battery level is equal to or over the predetermined threshold X, the iteration count control unit 130B proceeds to step T13 to set the iteration count of decoding “N0”. A state with the remaining battery level equal to or over the predetermined threshold X is referred to as a “mode 1”. If determining at step T12 that the remaining battery level is under the predetermined threshold X, the iteration count control unit 130B proceeds to step T14 to determine whether the remaining battery level is equal to or over a predetermined threshold Y. If determining that the remaining battery level is equal to or over the predetermined threshold Y, the iteration count control unit 130B proceeds to step T15 to carry out setting processing of the iteration count in accordance with the reception quality. A state with the remaining battery level under the threshold X and equal to or over the threshold Y is referred to as a “mode 2”. If determining at step T14 that the remaining battery level is under the threshold Y, the iteration count control unit 130B proceeds to step T16 to carry out setting processing of the iteration count in accordance with the distance between the antennas. A state with the remaining battery level under the threshold Y is referred to as a “mode 3”.

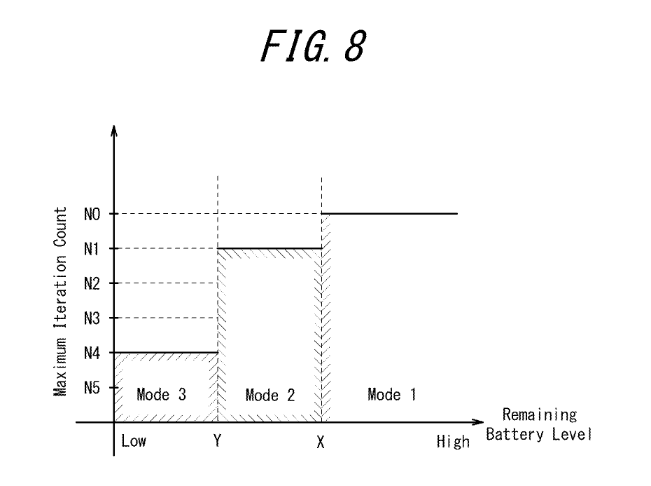

Here, conditions of the modes 1-3 of the remaining battery level and the iteration count of decoding set in accordance with the mode are described. FIG. 8 is a diagram illustrating a relationship between the mode of the remaining battery level and a maximum iteration count of decoding set by the iteration count control unit 130B. A horizontal axis shows the remaining battery level, whereas a vertical axis shows the maximum iteration count. If the remaining battery level is adequately high (mode 1), the iteration count control unit 130B sets the maximum iteration count to the convergence count (here, “N0”). This is to carry out decoding as many times as the convergence count, at which high quality decoding characteristics can be obtained although power consumption is increased by the decoding processing, as there is plenty of remaining battery level. If the remaining battery level is slightly low (mode 2), iterative decoding is carried out for the number of times less than the convergence count “N0”. Although a detailed description will be presented below, the iteration count control unit 130B sets the iteration counts N1-N3 in accordance with the channel quality in the mode 2. This is, in reducing the iteration count in order to reduce the power consumption as the remaining battery level is declined, to further reduce the iteration count based on a recognition that the reception data have only few errors when the channel quality is good, while increasing the iteration count in order to improve accuracy in error correction if the channel quality is not good and may thus generate errors in the reception data. Moreover, if the remaining battery level is low (mode 3), the iteration count control unit 130B sets the iteration count less than those in the modes 1, 2. At this time, the iteration count control unit 130B sets the iteration counts to N4, N5 in accordance with the distance between the antennas. While, similar to a case of the mode 2, the iteration count control unit 130B sets a smaller iteration count in accordance with the reception quality in order to reduce power consumption, it is intended to improve accuracy in error correction as much as possible without consuming power by calculation of the channel quality since the reception quality is estimated based only on the distance between the antennas.

Referring again to the flowcharts in FIG. 7, a setting processing of the iteration count setting processing (setting processing of the iteration count in the mode 2) in accordance with the reception quality at step T15 is described. FIG. 7(b) is a flowchart of an exemplary setting processing of the iteration count in accordance with the reception quality. First, at step T21, the channel quality calculation unit 160 determines whether the reception quality is obtained already, that is, the data (pilot signals and the like) that enable to calculate the reception quality (channel quality) are already obtained. If the channel quality calculation unit 160 determines that the reception quality is not obtained, the processing proceeds to step T23 where the iteration count control unit 130B sets the iteration count “N1”. The “N1” is a maximum iteration count assignable in the mode 2 and is set to the convergence count, at which the decoding characteristics converge adequately, if the reception quality is unknown. If determining at step T21 that the reception quality is already obtained, the processing proceeds to step T22 where the iteration count control unit 130B sets the iteration count in accordance with the reception quality, based on the following Table 3 stored in the memory unit 150B.

TABLE 3

| Reception Quality | Iteration Count |
|---|---|
| Reception Quality < C | N1 |
| C ≦ Reception Quality < D | N2 |
| D ≦ Reception Quality | N3 |

C, D: Thresholds of the reception quality (C < D), N1 ≧ N2 ≧ N3

If the reception quality is under the threshold C, the iteration count control unit 130B sets the iteration count to “N1”. If the reception quality is equal to or over the threshold C and under the threshold D, the iteration count control unit 130B sets the iteration count to “N2”. Additionally, if the reception quality is equal to or over the threshold D, the iteration count control unit 130B sets the iteration count to “N3”. Here, the thresholds of the reception quality satisfy C<D, whereas the iteration counts satisfy N1>N2>N3. This is because, when the reception quality is good, the iteration count can be set less than that for when the reception quality is not good. After setting of the iteration count at step T22 or T23, the processing returns to step T17 in FIG. 7(a).

Next, a setting processing of the iteration count (iteration count setting processing in the mode 3) in accordance with the distance between the antennas at step T16 is described. FIG. 7(c) is a flowchart of an exemplary setting processing of the iteration count in accordance with the distance between the antennas. First, at step T31, the antenna distance detection unit 140 detects the distance between two antennas ANT 1 and ANT 2 and transmits the distance to the iteration count control unit 130B. The iteration count control unit 130B sets (controls) the iteration count of decoding based on the table showing a relationship between the iteration count and the distance between the antennas stored in the memory unit 150. The following is the table stored in the memory unit 150, by way of example.

TABLE 4

| Distance between Antennas | Iteration Count |
|---|---|
| A ≦ Distance | N5 |
| Distance < A | N4 |

A: Threshold of the distance between the antennas, N4 ≧ N5

Based on the table 4, if the distance between the antennas is under the threshold A, the iteration count control unit 130B sets the iteration count to “N4”. If the distance between the antennas is equal to or over the threshold A, the iteration count control unit 130B sets the iteration count to “N5” (steps T32-T34). Here, the threshold A is a value at or over which the ANT 1 and the ANT 2 are less correlated and receive signals substantially as two antennas. And, the iteration counts satisfy N4>N5. This is based on the recognition that the reception quality is good if the correlation between the ANT 1 and the ANT 2 is low, and because the iteration count of decoding can be reduced than that for when the distance between the antennas is short and thus the antennas receive signals substantially as a single antenna. After setting of the iteration count at step T33 or T34, the processing proceeds to step T17 in FIG. 7(a). After processing at steps T13-T16, the reception unit 110 receives data including the error-correcting codes (step T17), and the iterative decoder 120 decodes the reception data in accordance with the iteration count (step T18).

The remaining battery level detection unit 180 keeps monitoring the remaining battery level during reception of the data and switches among the modes 1-3. If the remaining battery level is rapidly declined, the remaining battery level detection unit 180 may not carry out determination on the remaining battery level thereafter and the iteration count of decoding may be controlled in accordance only with the distance between the antennas. It is preferred to indicate that the remaining battery level is low using, for example, a display unit, a vibration unit, a speaker, a light emitting section or the like of the wireless communication terminal 100B with a message, a specific icon, a vibration, a sound, a glimmer or the like.

As stated above, according to the third embodiment, it is possible to reduce delay and power consumption caused by decoding processing by controlling the iteration count of the decoder so as not to deteriorate the decoding characteristics while reducing power consumption in accordance with the remaining power level (remaining battery level) available to supply to the terminal itself. Moreover, it is also possible to reduce the time and power consumption necessary for decoding processing by, taking advantage of the diversity scheme, reducing the iteration count of decoding if the correlation between the antennas is low and the reception quality is good.

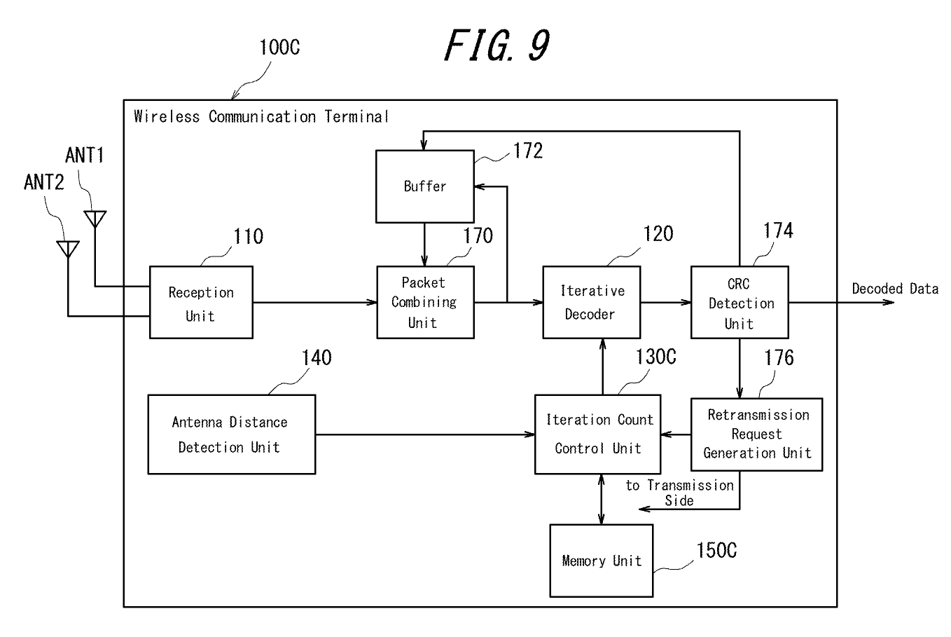

Next, a fourth embodiment of the present invention is described. FIG. 9 is a schematic block diagram of a wireless communication terminal according to the fourth embodiment of the present invention. In the figure, the same functional units as those of the wireless communication terminal 100 shown in FIG. 2 are denoted by identical reference signs and descriptions thereof are omitted. A wireless communication terminal 100C further includes a packet combining unit 170, a buffer 172, a CRC detection unit 174 and a retransmission request generation unit 176. The wireless communication terminal 100C carries out error correction by using a known HARQ (Hybrid Automatic Repeat Request) scheme. HARQ is a scheme applying a packet combining technique, for example, to ARQ (Automatic Repeat Request), which is control, when a reception side receives error data (packets), to request a transmission side to retransmit the data (error packets). The packet combining technique is to combine packets of data previously received and newly received data retransmitted from a communication counterpart apparatus (base station, for example). According to the fourth embodiment, the iteration count of decoding using HARQ is varied in accordance with the distance between the antennas and the number of retransmission requests. Although HARQ using Chase Combining is used by way of example in the present embodiment, the present invention is not limited to it. In addition, since HARQ is a known scheme, a detailed description thereof is omitted.

A iteration count control unit 130C of the wireless communication terminal 100C sets the iteration count of decoding based on the number of retransmission requests by the retransmission request generation unit 176 and the distance between the antennas detected by the antenna distance detection unit 140. The memory unit 150C stores a table of the iteration counts corresponding to the numbers of retransmission requests by the retransmission request generation unit 176 and the distances between the antennas.

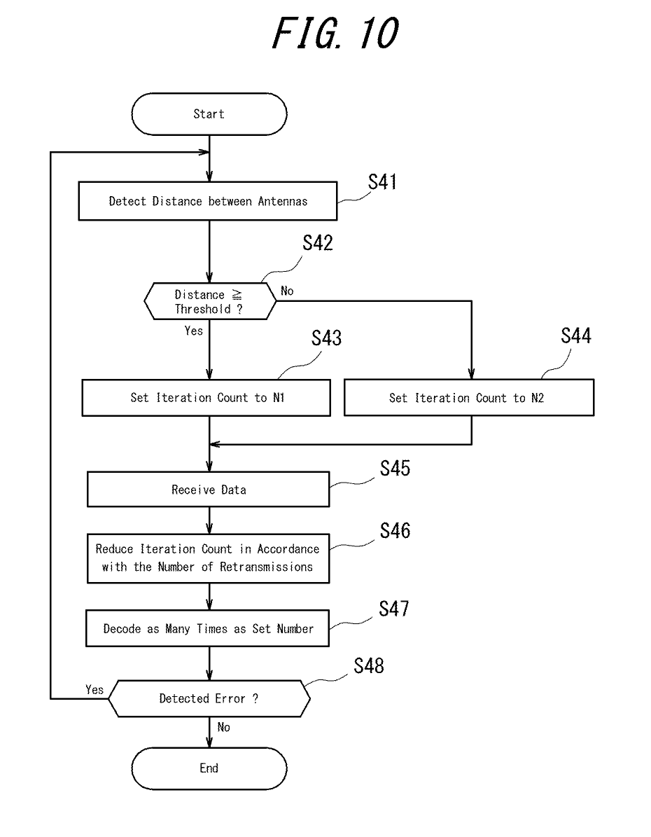

Next, processing by the wireless communication terminal according to the fourth embodiment of the present invention is described with reference to a flowchart. FIG. 10 is a flowchart of exemplary processing by the wireless communication terminal 100C according to the fourth embodiment of the present invention. First, at step S41, the antenna distance detection unit 140 detects the distance between two antennas ANT 1 and ANT 2 and transmits the distance to the iteration count control unit 130C. The iteration count control unit 130C sets the iteration count of decoding based on the table of a relationship between the iteration count and the distance between the antennas stored in the memory unit 150C. This table may be the above Table 1. If the distance between the antennas is under the distance A, the iteration count control unit 130C sets the iteration count to “N2”. If the distance between the antennas is equal to or over the threshold A, the iteration count control unit 130C sets the iteration count to “N1” (steps S42-S44). Since the iteration counts are the same as those according to the first embodiment, descriptions thereof are omitted. Next, at step S45, the reception unit 110 receives data. Then, the iteration count control unit 130C reduces the iteration count in accordance with a previous number of retransmission requests stored in the memory unit 150C (step S46). HARQ allows the packet combining unit 170 to combine the data previously received and stored in the buffer 172 and data newly retransmitted. Accordingly, since an absolute amount of the data is increased as the number of retransmissions is increased and thus the quality of the data transmitted to the iterative decoder 120 is more improved, the iteration count of decoding is reduced as the number of retransmissions is increased according to the present embodiment. Then, at step S47, the iterative decoder 120 carries out iterative decoding as many times as the iteration count. The CRC detection unit 174 detects a CRC (Cyclic Redundancy Check) codes in the data processed by the iterative decoder 120 and determines whether there is an error (step S48). If an error is detected, the retransmission request generation unit 176 transmits the retransmission request and the processing returns to step S41. If no error is detected, the processing ends.

Now, advantages of the present invention are stated again. As described above, the wireless communication terminal of the present invention, different from the conventional art which uselessly iterates decoding in accordance with the predetermined count even when the reception quality is good and decoding characteristics converge quickly, takes advantage of the diversity scheme and reduces the iteration count of decoding when the correlation between the antennas is low and the reception quality is good, and thus can reduce the time and power consumption necessary for decoding in comparison with the conventional art. In addition, even if the distance between the antennas is short and the antennas receive signals substantially as a single antenna, it is possible to reduce the iteration count of decoding in accordance with the reception quality.

In addition, the conventional art which controls the iteration count by calculating the channel quality has a problem that power consumption, that is, battery consumption is increased with load placed by calculation of the channel quality. Accordingly, it is not ideal to carry out iterative decoding in accordance with the conventional art if the remaining power level (remaining battery level) is low. In contrast, according to the present invention, it is possible to reduce the delay and power consumption caused by decoding processing by controlling the iteration count of the decoder so as not to deteriorate the decoding characteristics, while reducing power consumption in accordance with the remaining power level (remaining battery level) available to supply to the terminal itself. Moreover, taking advantage of the diversity scheme, the iteration count of decoding is reduced if the correlation between the antennas is low and the reception quality is good, thereby it is possible to reduce the time and power consumption necessary for decoding processing, in comparison with the conventional art.

Although the present invention is described based on the figures and the embodiments, it should be understood that various changes and modifications can be easily made by those skilled in the art based on the present invention. Therefore, those changes and modifications are included in a scope of the present invention. For example, each component and a function included in each means can be rearranged avoiding a logical inconsistency, so as to combine a plurality of components or to divide a component. For example, the iteration counts N1-N4 shown in the table in each embodiment can be different in each embodiment. In addition, although two thresholds C, D of the reception quality are used in the second embodiment, more than two thresholds can be provided. Also, the present invention is applicable not only to the flip-type mobile phone as the wireless communication terminal shown in FIG. 1 but to any wireless communication terminal having a plurality of antennas with a relative distance therebetween can be varied. Moreover, the power available to supply to the terminal itself is not limited to one from the battery loaded therein but may include power from an external battery charger. Furthermore, although the Turbo codes are used in the above embodiments, the present invention is not limited thereto but may also be applicable to error correction schemes such as LDPC and the like that carry out iterative decoding.

### REFERENCE SIGNS LIST

100, 100A, 100B, 100C wireless communication terminal
110 reception unit
120 iterative decoder
130, 130A, 100B, 130C iteration count control unit
140 antenna distance detection unit
150, 150A, 150B, 150C memory unit
160 channel quality calculation unit
170 packet combining unit
172 buffer
174 CRC detection unit
176 retransmission request generation unit
180 remaining battery level detection unit
ANT 1-ANT 3 antenna
200 wireless communication terminal
210 reception unit
220 iterative decoder
230 channel quality calculation unit
240 iteration count calculation unit

1. A wireless communication terminal having a plurality of antennas with a variable relative distance comprising:
a decoder for iterative decoding of reception signals including an error-correcting code received by the plurality of antennas;
an antenna distance detection unit for detecting a distance between the plurality of antennas; and
a control unit for controlling an iteration count of decoding by the decoder in accordance with the distance between the antennas detected.

2. The wireless communication terminal according to claim 1, wherein the control unit, if the distance between the antennas is over a predetermined value, reduces the iteration count of decoding in comparison with an iteration count of decoding when the distance between the antennas is under the predetermined value.

3. The wireless communication terminal according to claim 1, further comprising a channel quality calculation unit for calculating quality of a communication channel from the reception signals received by the plurality of antennas, wherein
the control unit, if the distance between the antennas is under a predetermined value, controls the iteration count of decoding in accordance with the quality of the communication channel calculated by the channel quality calculation unit.

4. The wireless communication terminal according to claim 1, further comprising a determination unit for determining whether data decoded by the decoder has an error, and
a retransmission request unit for requesting retransmission of data based on a result of determination by the determination unit, wherein
the control unit further controls the iteration count of decoding by the decoder in accordance with the number of retransmission requests requested by the retransmission request unit.

5. The wireless communication terminal according to claim 1, further comprising a detection unit for detecting a remaining power level available to supply to the wireless communication terminal, wherein
the control unit, if the remaining power level detected by the detection unit is under a predetermined value, controls the iteration count of decoding by the decoder in accordance with the distance between the antennas detected by the antenna distance detection unit.

6. The wireless communication terminal according to claim 5, further comprising a channel quality calculation unit for calculating quality of a communication channel from the reception signals received by the plurality of antennas, wherein
the control unit, based on the remaining power level detected by the detection unit, switches between control of the iteration count of decoding in accordance with the quality of the communication channel calculated by the channel quality calculation unit and control of the iteration count of decoding in accordance with the distance between the antennas detected by the antenna distance detection unit.

7. A wireless communication terminal having a decoder for iterative decoding of a reception signal including an error-correcting code comprising:
a detection unit for detecting a remaining power level available to supply to the wireless communication terminal; and
a control unit for controlling an iteration count of decoding by the decoder in accordance with the remaining power level detected.

8. A communication control method of a wireless communication terminal having a plurality of antennas with a variable relative distance comprising the steps of:
iteratively decoding reception signals including an error-correcting code received by the plurality of antennas;
detecting a distance between the plurality of antennas; and
controlling an iteration count of decoding by the decoder in accordance with the distance between the antennas detected at the step of detection.

9. A communication control method of a wireless communication terminal having a decoder for iterative decoding of a reception signal including an error-correcting code comprising the steps of:
detecting a remaining power level available to supply to the wireless communication terminal; and
controlling an iteration count of decoding by the decoder in accordance with the remaining power level detected at the step of detection.
